(19) United States
(12) Patent Application Publication
(10) Pub. No.: US 2017/0309738 A1
(43) Pub. Date: Oct. 26, 2017

(54) VERTICALLY STRUCTURED POWER TRANSISTOR WITH TRENCH SUPPLY ELECTRODE

(71) Applicant: CENTRE NATIONAL DE LA RECHERCHE SCIENTIFIQUE (CNRS, PARIS (FR)

(72) Inventors: Moustafa ZERARKA, TOULOUSE (FR); Patrick AUSTIN, BONREPOS-RIQUET (FR); Marise BAFLEUR, CASTANET TOLOSAN (FR)

(21) Appl. No.: 15/528,831

(22) PCT Filed: Nov. 24, 2015
(86) PCT No.: PCT/FR2015/053189

§ 371 Date: May 23, 2017

(30) Foreign Application Priority Data
Nov. 24, 2014 (FR) 1461381

(51) Int. Cl. H01L 29/78; H01L 29/66; H01L 29/10; H01L 29/417; H01L 29/739

(52) U.S. Cl. CPC H01L 29/7802; H01L 29/7396; H01L 29/66727; H01L 29/1095; H01L 29/41766; H01L 29/6634

(57) ABSTRACT

The invention relates to a vertically structured power transistor, such as a VD-MOS or an IGBT, having a cell comprising: two symmetrical source layers (308), preferably N+ doped, which extend from a front surface (312) of the semiconductor substrate; a well layer (307), preferably P doped, comprising an area having a higher doping concentration (307b) that extends from one source layer to the other; a source/well NP junction (J3) between the source layer and the well layer. According to the invention, a cathode formed on the front surface (312) of the semiconductor substrate has a trench portion (309) with a bottom (313) that extends into the area having a higher doping concentration (307b) of the well layer (307) to a certain depth away from the source/well NP junction (J3).

The present invention essentially relates to power transistors of the VDMOS (Vertical Double diffusion Metal Oxide Semiconductor) and IGBT (Insulated Gate Bipolar Transistor) type.

VDMOSs are attractive devices for spatial and aeronautical applications due to the simplicity of their gate drive, low volume and weight of the circuits obtained with respect to those incorporating bipolar transistors. Moreover, they are more efficient in high frequency ranges and for switched-mode power supplies.

VDMOSs are field-effect transistors, i.e. having single-pole components using only one type of current carrier. They are therefore distinguished by very short switching times (of the order of 100 ns) because unlike bipolar components, there is no delay associated with the recombination of minority carriers in the blocking phase. This type of transistor is used in many applications from 10 to 500 kHz for current ranges extending from 10 à 1200 V for a nominal range of current from a few hundred milliamps to a few amps. It should be noted that the DMOS (Double diffusion Metal Oxide Semiconductor) transistor exists in vertical (VDMOS) or lateral (LDMOS) configurations. The vertical configuration has better voltage performance and is less limited in terms of current than the lateral configuration.

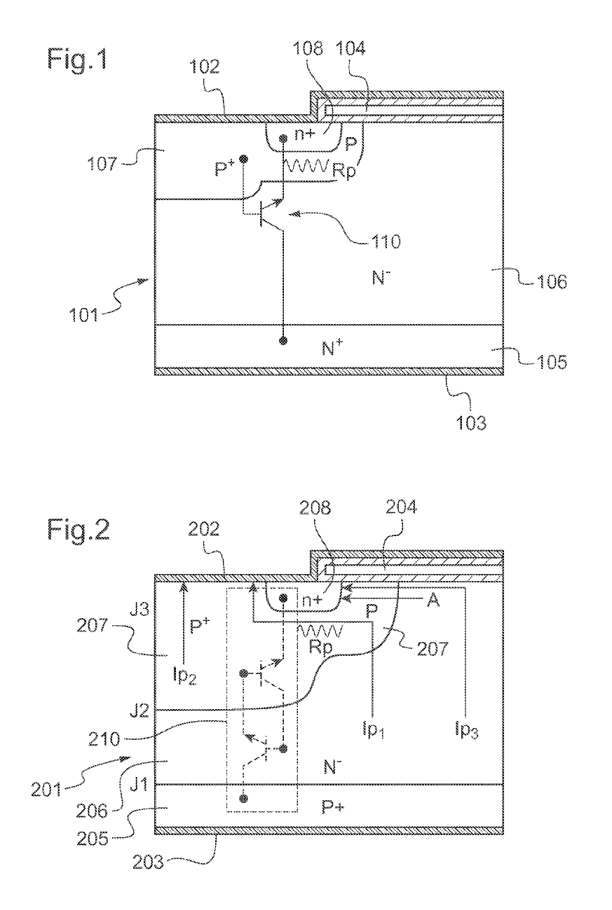

A VDMOS can be obtained as follows. Starting from a substrate of the N⁺type on which an N⁻ epitaxial layer is grown, successive islands of the P⁺/P type called bodies, then in these bodies source regions of the N⁺ type, are diffused. The metallization of the substrate gives a drain connection. The P⁺/P islands are short-circuited by the metallization of the source. An insulating layer of polysilicate coating a gate connection is deposited on the oxide layer. The component shown in FIG. 1 is obtained in this way.

A VDMOS thus comprises: a semiconductor material 101 on each side of which is located a source 102 and a drain 103; an insulated gate 104 on the same side as the source 102; three NPN layers in the semiconductor material, namely two opposing PN junctions that prevent conduction of the current; these three NPN layers being a first layer N formed by the N⁺ substrate 105 and the N⁻ epitaxial layer 106, a second P layer formed by a body 107, and a third N layer formed by an N⁺ source region 108.

Applying a positive voltage V_{GS}to the gate creates an electric field that pushes out the majority carriers from the P/P⁺ islands, creating an inversion of the type of the region. A current can them flow in a channel, vertically in the substrate and in the epitaxial layer, then horizontally in the inverted doping region of each P/P⁺ island.

The structure of an IGBT is based on that of a VDMOS: the thickness of the support 201 is used in order to separate the collector (drain) 203 from the emitter (source) 202. An N-doped epitaxial region 206 allows a channel to appear when electrons are injected via the gate 204, i.e. when V_{G}>0 (on-state). An IGBT can be seen in FIG. 2. The double diffusion technique is used in order to create P/P⁺ doped bodies 207 close to the source 202, the doped P/P⁺ region having the function (see below) of reducing the risks of destructive single events.

The main difference between a vertical MOSFET and an IGBT is the existence of a P+ substrate layer 205 that is heavily doped on the collector side, while the substrate is N⁺-doped in a VDMOS. This layer injects holes into the N⁻ epitaxial layer 206, which has the effect of reducing the voltage drop in the on-state and converting it into a bipolar transistor. IGBT therefore has four main layers (from the emitter 202 to the drain 203) N-P-N-P.

An IGBT is a hybrid transistor, grouping together a field-effect transistor at the input and a bipolar transistor at the output. It is thus controlled via the gate voltage (voltage V_{G} between the gate and the emitter) applied thereto, but its conduction characteristics (between collector and emitter) are those of a bipolar transistor. This hybrid structure gives it the low control energy cost of a MOSFET, with the lower conduction losses (for a given chip surface area) of a bipolar transistor. In addition, IGBTs can generate a much higher voltage than that generated by MOSFETs.

In the off-state, the N⁻ epitaxial layer 106 or 206 supports the voltage (both in an IGBT and in a VDMOS). The lighter the doping and/or the smaller the thickness of the N⁻ epitaxial layer, the higher will be this maximum voltage. For good performance, a transistor must be able to support the highest possible voltage at its drain or collector.

As stated above, VDMOS and IGBTs are often used in spacecraft and aeronautical craft. However, natural environmental radiation presents many dangers for these electronic components. Two types of environmental radiation are distinguished:
the space radiation environment, comprising cosmic radiation (protons from 100 to 10⁶ MeV, high-energy α particles, heavy ions from 1 to 10¹⁴ MeV), solar eruptions (protons from 10 MeV to 1 GeV, α particles from 10 MeV to several hundred MeV, heavy ions), solar winds (protons up to 100 KeV, electrons up to several keV, α particles), radiation belts (protons up to several hundred MeV, electrons of several MeV);
the atmospheric radiation environment, including cosmic showers or atmospheric showers, in which highly energetic particles originating from cosmic radiation can ionize elements of the atmosphere and trigger nuclear chain reactions, forming a chain of secondary particles such as protons, neutrons or pions capable of interacting with on-board systems and more particularly with semiconductors.

Although atmospheric environmental radiation is less aggressive, failures have been noted in railway equipment and various studies have shown that radiation failures occur in power components at ground level.

Cumulative phenomena such as the effects of ionizing doses are at the origin of functional errors and contribute to a deterioration of a device over time.

Phenomena induced by a single particle, called “single event effects”, occur unexpectedly, and can have irreversible consequences for the correct operation of the systems. Some of these single event effects give rise to a minor failure that does not cause permanent damage and the devices can be reset by correcting signals. Other effects can result in permanent degradation and even destruction of the device. These destructive events are instances of single event burn-out that affect VDMOS and IGBTs and single latch-up events that only affect IGBTs.

VDMOSs have one undesirable feature: under certain conditions, a parasitic bipolar NPN transistor 110 is formed as shown in FIG. 1. The N⁺ source region 108 constitutes the emitter of this parasitic transistor; the P body 107 constitutes the base thereof, and the N⁻ epitaxial layer 106 acts as collector.

Conduction can be initiated in this normally inactive parasitic bipolar transistor during rapid switching (high dV/dt) or also by the passage of ionizing radiation. Initiating its conduction, coupled with the avalanche mechanisms, can then cause an irreversible runaway of the current that leads to burn-out. The operating principle requires being in inverse polarization in the off-state with a sufficiently wide space-charge region making it possible to generate carriers by avalanche. The phenomenon is initiated by capturing holes diffusing laterally below the source in the body until directly polarizing the emitter/base junction of the parasitic bipolar transistor. Once the latter is active, electrons are injected from the emitter towards the epitaxial region by the bipolar effect.

If the electric field condition is sufficient in the epitaxial region, the consequence of this rush of electrons is to initiate the avalanche phenomenon. In fact, the electrons passing through the space charge region acquire sufficient kinetic energy to remove an electron from an atom of the crystal lattice, thus creating an electron-hole pair during the collisions. The phenomenon is self-sustaining: the avalanche supplies more and more holes to the parasitic bipolar transistor, causing a larger injection of electrons of the bipolar transistor, which feeds the avalanche, and so on and so forth. The very high resulting current that passes into a single cell leads to the destruction of the component by thermal runaway. In the case of an incident ionizing particle, the holes initially originate from the ionization track created by the passage thereof.

If the current originating from the streamer is very weak and/or if the electric field in the space charge region is insufficient, the parasitic bipolar transistor becomes inactive and the phenomenon is indicated simply by a transitory current followed by a return to the initial off-state.

The parasitic bipolar transistor must therefore be desensitized. The highest probability of resulting in a burn-out in the event of irradiation of a VDMOS obtains for an ion that penetrates into the inter-cell region and passes through the entire space-charge region, because in this case burn-out occurs, even for a relatively low linear energy transfer. Destructive events are noted as soon as the polarization voltage exceeds 15% of the breakdown voltage (i.e. from 90V for a transistor having a breakdown voltage of 600V). Below 15% of its breakdown voltage, the VDMOS is considered insensitive to radiation because the current induced by an ionizing particle is not maintained.

In a somewhat similar fashion, IGBTs have an undesirable feature responsible for the phenomenon of latch-up (sometimes known as locking). In fact, under certain conditions, the four N-P-N-P layers of the IGBT can become vertically on-state in the manner of a thyristor 210 (see FIG. 2), due to the presence of a parasitic transistor between the emitter and base of the main bipolar transistor. When such locking occurs, the transistor remains on-state, with destructive effects, until the power supply is switched off. Unlike MOSFETs, the mechanism of ionization by impact is not necessary for triggering this parasitic functioning. This means that the main cause leading to the destruction of the IGBT when the latter is affected by incident radiation is the initiation of conduction and locking of the NPNP parasitic thyristor.

Once again, the probability of resulting in the destruction of the transistor by latch-up is maximum when the incident ionizing particle penetrates into the inter-cell region and passes through the entire space charge region. In a planar IGBT, destructive events can be noted as soon as the polarization voltage exceeds 90V.

In order to reduce the major problem of latch-up in IGBTs and burn-out in VDMOSs and IGBTs, to date two principal routes have been investigated, relating to the structure of the transistors:
reducing the lateral resistance Rp of the body. This reduction is obtained by means of the presence of an overdoped P⁺ region in each P body. Throughout the description, by the expression “P⁺ overdoping region” is meant a region having undergone at least two doping operations (by implantation, diffusion, etc.). A technique of hardening against latch-up for IGBTs was thus proposed by adjusting the width of the P⁺ overdoping region of the emitter so as to reduce the effectiveness of the NPNP parasitic thyristor injection. But this P⁺ overdoping region also has the effect of increasing the threshold voltage of switching (voltage applied to the gate/base, either V_{G} or V_{BE}, above which the transistor becomes on-state and below which it is off-state), which is not desirable;
V using a trench gate, (Trench) for which new etching technologies have been developed. These technologies are however relatively difficult to implement, and the result with respect to immunity to latch-up or burn-out is not sufficient, in particular under extreme conditions of use of the transistor.

Apart from these two structural approaches, it has also been proposed to improve the gate drive procedures, i.e. to protect a transistor by adding to the circuit external to the transistor, protection elements for the control of certain regions of the transistor and for maintaining polarization of the base/emitter junction of a parasitic transistor, as envisaged by FR2627325.

The drawback of these protection elements is that they only protect a single cell and must therefore be multiplied by the number of cells present in a conventional component, which may become complex or even impossible with a large number of cells.

All these developments mean that the phenomena of latch-up and burn-out are currently quite well managed under normal conditions of use of the transistors. But these phenomena remain a major problem under extreme conditions of use of the transistors, such as corrosive environments, a very high or very low temperature, vibrations, or also radiative environments.

The invention aims to overcome these drawbacks by proposing a power transistor that is insensitive, or only slightly sensitive, to radiation phenomena, and in particular to heavy ion irradiation, i.e. a transistor that is not very likely to experience a destructive event of the latch-up or burn-out type in the event of irradiation, both in the on-state and in the off-state, without degradation of the voltage performance, with respect to the known power transistors.

A further objective of the invention is to achieve this insensitivity result by means of the structure of the transistor itself (structural approach), i.e. independently of the circuit external to the transistor, as opposed to the prior solutions proposing protection circuits the role of which is to switch off the voltage at the terminals of the transistor temporarily in order to de-energize an untimely initiation of the parasitic structures thereof.

A further objective of the invention is to provide an optimal preferred structure that confers both a high immunity against parasitic initiation while still retaining the static features, including the threshold voltage, and the dynamic features of the standard known structures.

The invention thus aims to provide power transistors that can be used with complete safety in the aerospace field.

A further objective of the invention is to achieve this end without significantly increasing the cost of manufacture of the power transistor.

To this end, the invention proposes a power transistor with a vertical structure having a cell exhibiting a plane of symmetry and comprising a semiconductor support, as well as:
inside the semiconductor support:
two symmetrical source layers, having a first type of conductivity (preferably N⁺), starting from a front face of the semiconductor support,
a body layer having a second type of conductivity (preferably P) opposite to the first type, below the source layers, said body layer comprising an overdoping region (P⁺) that extends from one source layer to the other,
an NP source/body junction between each source layer and the body layer.
on the front face of the semiconductor support:
a first power supply electrode connecting the two symmetrical source layers and the body layer, this first power supply electrode being referenced “cathode” throughout the application, but it can also be called “source” in the case of a field-effect transistor (VDMOS) or “emitter” in the case of a bipolar transistor (IGBT).
a control electrode (gate or base) that is insulated and flat (hence a “planar” VDMOS or IGBT is obtained as opposed to the “trench” IGBTs, the base of which is a trench);
on a rear face of the semiconductor support, opposite to the front face: a second power supply electrode, referenced anode throughout the application, but which can also be called “drain” in a field-effect transistor (VDMOS) or “collector” in a bipolar transistor (IGBT),

In standard fashion, throughout the application, the transistor is viewed in a position in which its plane of symmetry is vertical, its front face is the upper face of the semiconductor support, its rear face is the lower face of the semiconductor support, the vertical direction (direction of gravity) is orthogonal to the rear face.

The transistor according to the invention is characterized in that:
the cathode has a trench portion formed in an etching arranged in the front face of the semiconductor support between the two source layers, said trench cathode portion comprising a base situated in the body layer at a distance, depthwise (i.e. in the vertical direction) from the NP source/body junction so as to distance from the source layer any lateral current that, in operation, passes through the body layer below the source layer until reaching the cathode,
the overdoping region extends below the base of the cathode portion in the form of a trench and at least partially below each source layer,
the etching has a ratio L_{T} to Ls (L_{T} / Ls) called standardized trench length, greater than or equal to 15/20, where L_{T} denotes half of a maximum dimension of the etching in a transverse direction orthogonal to the plane of symmetry of the cell and Ls denotes the distance between the plane of symmetry and the control electrode in the transverse direction. In other words, Ls represents the internal half-length of the cathode (the latter terminating at the place where the insulated control electrode begins) in the transverse direction. It will be noted that, by definition, L_{T} is strictly less than Ls, i.e. L_{T} / Ls is less than 1. The ratio L_{T}/Ls is therefore, according to the invention, comprised between 0.75 (inclusive) and 1 (exclusive).

In standard fashion, throughout the description, by “transverse direction” is meant the (horizontal) direction orthogonal to the (vertical) plane of symmetry of the cell.

Owing to the presence of the trench, it is possible to form an overdoping region that extends below the whole, or almost the whole, of each source layer and thus protects the latter.

Conventionally, the cell of the transistor also comprises, in the semiconductor support:
an epitaxial layer, having the first type of conductivity (preferably N⁻), below the body layer,
a PN body/epitaxial layer between the body layer and the epitaxial layer.

It should be noted that, in the definition hereinafter, the term “epitaxial” in the expression “epitaxial layer” is not intended to limit this layer insofar as its method of manufacture is concerned. The invention also applies if the layer that is called “epitaxial layer” herein is not obtained by epitaxy

Advantageously and according to the invention, the base of the trench cathode portion extends depthwise at a distance from the PN body/epitaxial junction.

The invention extends to a method for the manufacture of a transistor according to the invention.

In particular, the invention extends to a method for the manufacture of a transistor comprising
forming, starting from a front face of a semiconductor support, two symmetrical source layers, having a first type of conductivity (preferably N⁺), and a body layer, having a second type of conductivity (preferably P/P⁺) opposite to the first type.
after forming the source and body layers, forming a cathode on the front face of the semiconductor support, short-circuiting the two source layers and the body layer.

The method according to the invention is characterized in that:
etching is performed on the front face of the semiconductor support before forming the source and body layers,
at least two doping operations are carried out of the second type of conductivity (preferably P⁺), so as to obtain an overdoping region around the etching and at least partially below the two source layers.

In a possible form of the power transistor according to the invention, the trench cathode portion forms an arris in the body layer, and more specifically in the overdoping region, at a distance from the NP source/body junction. This arris allows a concentration of the lines of the electrical field that participates in channelling the current and distancing the latter from the source layer. A trench shape without an edge, with smooth contours, is also possible.

In a possible form of the power transistor according to the invention, the trench cathode portion has vertical lateral walls. As a result, the NP source/body junction obtained is substantially horizontal. As the doping diffuses orthogonally to the wall from which it is implanted, it also results therefrom that the overdoping region according to the invention can extend, from each vertical lateral wall, below the adjacent source layer up to a vertical plane delimiting the control electrode, so as to protect the source layer effectively.

With opposite lateral walls inclined in such a way as to form a V in the semiconductor support, it would be difficult to obtain an overdoping layer extending over the entire length of the source layer, not only at the level of the NP source/body junction, but also at a distance, depthwise, therefrom. Conversely, with opposite lateral walls inclined such that the etching presents a length increasing with the depth, the overdoping region obtained would risk extending beyond the vertical plane delimiting the control electrode and thus disturb the control.

In a possible form of the power transistor according to the invention, the trench cathode portion has a vertical section that is rectangular in shape. In this case, it has vertical lateral walls and a horizontal flat base, as well as an arris at the intersection of the base and each lateral wall. This embodiment has proved to be the most effective with respect to the technical problem that the invention is intended to solve. Furthermore, it is easy to produce.

In a possible form of the power transistor according to the invention, for each source layer, the ratio W_{T} to X_{N+} is greater than or equal to 2, where W_{T}, called trench depth, denotes the maximum dimension of the etching in the vertical direction, in other words a distance between the plane containing the front face of the semiconductor support before etching (front face taken at the level of the control electrode or of the source layer for example) and the plane containing the front face of the semiconductor support taken at the level of the etching, at the base of the etching, and X_{N+}, called depth of the source layer, denotes the maximum dimension of the source layer in the vertical direction, in other words a maximum distance between the NP source/body junction and the plane containing the face before etching (front face taken at the level of the source layer for example), this maximum dimension in the vertical direction of the source layer capable of being observed at the level of the lateral wall of the trench cathode portion adjacent to said source layer. A ratio W_{T} to X_{N+} greater than 1 is sufficient to obtain an IGBT that is robust against latch-up under normal conditions of use. When it is greater than or equal to 2, the IGBT becomes more robust against radiation and in particular, heavy ions. Preferably, the ratio W_{T} to X_{N+} is equal to 4. Over 4, the VDMOS according to the invention is totally insensitive to irradiation by heavy ions, while the IGBT is so up to a polarization voltage of the order of 80% of its breakdown voltage.

In a possible form of the power transistor according to the invention, the difference between W_{T} and X_{N+} is at least equal to 1 μm.

In a possible form of the power transistor according to the invention, X_{P+} is greater than or equal to 9 μm, where X_{P+}, called depth of overdoping below the trench, denotes the maximum distance in the vertical direction between the base of the trench cathode portion and the base of the overdoping region, which preferably corresponds with the base of the body, i.e. with the PN body/epitaxy junction. In a preferred version of the invention, the structure of the power transistor has the following dimensions:

W_{T}=4 μm, L_{T}=16 μm, X_{P+}=10 μm.

The invention extends to a transistor characterized in combination by all or part of the features mentioned heretofore and hereinafter.

The invention also extends to a power component, characterized in that it comprises a multitude of power transistors according to the invention.

Other details and advantages of the present invention will become apparent on reading the following description, which refers to the attached schematic drawings and relates to a preferred embodiment, given non-limitatively. In these drawings:

FIG. 1 is a diagrammatic view in vertical cross section of a half-cell of a standard VDMOS of the prior art.

FIG. 2 is a diagrammatic view in vertical cross section of a half-cell of a standard IGBT of the prior art.

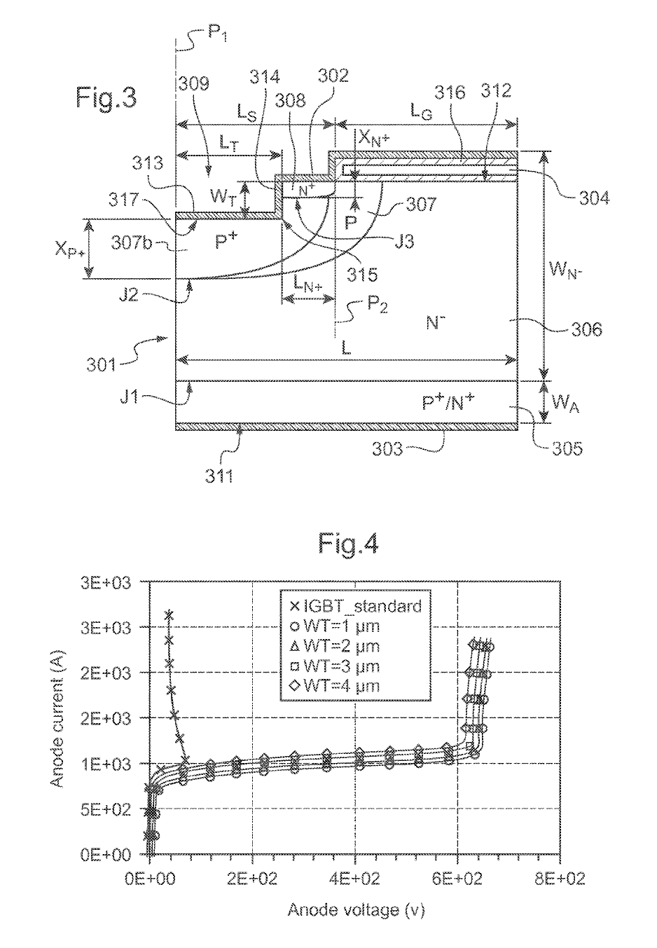

FIG. 3 is a diagrammatic view in vertical cross section of a half-cell of a power transistor according to the invention.

FIG. 4 is a graph representing static characteristics, namely the anode current (on the y axis) as a function of the polarization voltage (on the x-axis) for a standard IGBT of the prior art and for various embodiments of an IGBT according to the invention having different values for the trench depth W_{T}.

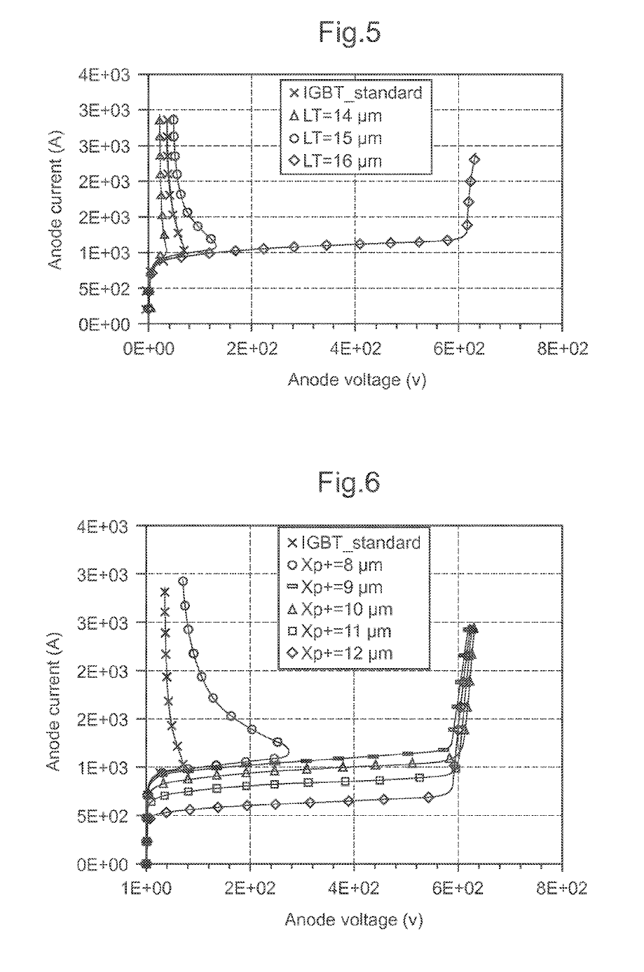

FIG. 5 is a graph representing static characteristics, namely the anode current (on the y axis) as a function of the polarization voltage (on the x-axis) for a standard IGBT of the prior art and for various embodiments of an IGBT according to the invention having different values for the trench length L_{T}.

FIG. 6 is a graph representing static characteristics, namely the anode current (on the y axis) as a function of the polarization voltage (on the x-axis) for a standard IGBT of the prior art and for various embodiments of an IGBT according to the invention having different values X_{P+} for overdoping below the trench.

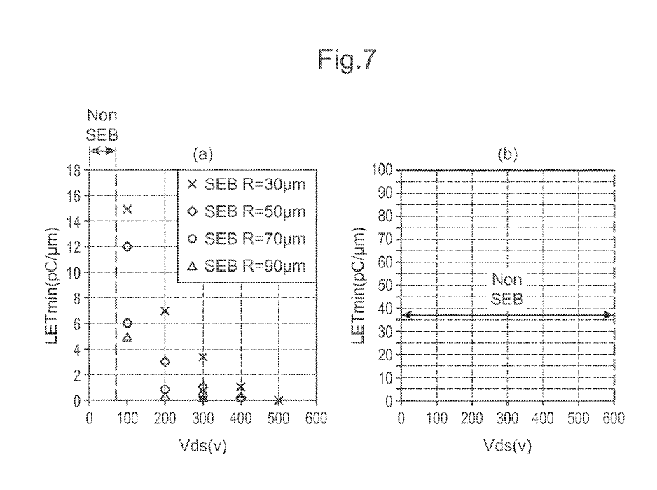

FIG. 7 illustrates the linear energy transfer LET necessary to cause a burn-out for different polarizations and different depths of penetration (“ranges”) for heavy ions originating from the front face of a standard VDMOS (graph on the left (a)) and a VDMOS according to the invention (graph on the right (b)).

As can be seen in FIG. 3, a power transistor according to the invention comprises a semiconductor support 301 as well as, from the bottom to the top of the figure:
an anode 303 formed by a (metallic) conductive layer arranged on a rear face 311 of the semiconductor support 301,
a substrate 305, which is preferably P⁺-doped in the case of an IGBT according to the invention, and which is preferably N⁺-doped in the case of a VDMOS according to the invention.
an epitaxial layer 306 preferably weakly N⁻-doped,
a body layer 307, preferably P-doped and comprising a P⁺ overdoping region referenced 307b,
a source layer 308, preferably heavily N⁺-doped, the complete cell thus comprising a second source layer, symmetrical with the layer 308 shown with respect to the plane of symmetry P1;
a control electrode 304 (also called gate)
an insulating layer 316 based on silicon dioxide (SiO₂) for insulating the control electrode 304,
a cathode 302 formed by a metallic conductive layer deposited on a front face 312 of the semiconductor support 301 and over the insulating layer 316. The front face 312 is flat apart from an etching described hereinafter.

It should be noted that the source layer 308 here extends transversally below the cathode 302 up to the edge of the control electrode 304, i.e. up to the vertical plane P2 that delimits said control electrode 304.

According to the invention, the cathode 304 has a trench portion 309 that penetrates into the body layer 307, and more specifically into the P⁺ overdoping region 307b of the body layer. It will be noted that the trench portion 309 of the cathode is in contact with this P⁺ overdoping region 307b over its entire length L_{T} and over a part of its height W_{T}. Over the remainder of its height W_{T}, the trench portion 309 of the cathode is in contact with the N⁺ source layer 308.

In the non-limitative example shown, the trench cathode portion 309 has a vertical section of rectangular shape, with flat, vertical lateral walls 114, and a flat, horizontal base 313. At the intersection of the base 313 and each lateral wall 314, a rectilinear arris 315 can also be observed. The horizontal section of the trench portion 309 of the cathode is also rectangular, preferably square.

According to the invention, the standardized trench length L_{T}/Ls is greater than or equal to 15/20 (0.75) and less than 1 by definition. In a preferred version, the standardized trench length L_{T}/Ls is equal to 16/20. It should be noted furthermore that in FIG. 3, L_{N+} denotes the maximum length of each source layer 308, i.e. the maximum dimension of the source layer 308 in the transverse direction.

The effects of the half-length of the trench L_{T} can be observed in FIG. 5, which was established with IGBTs according to the invention for which W_{T}=4 μm, X_{P+}=9 μm, L_{S}=20 μm and L_{T} varies, and with a standard comparable IGBT (trenchless IGBT having the same dimensions apart from the dimensions resulting from the trench). The inventors thus established that with a standardized trench length value of 15/20, the latch-up voltage (anode voltage beyond which latch-up occurs) value is already double with respect to a standard structure and that, for L_{T}/L_{S}=16/20, the latch-up phenomenon does not occur at all. In addition, the inventors have shown that the value of the trench half-length L_{T} has no influence on the value of the threshold voltage of the transistor.

In the preferred version of the invention, the trench depth W_{T} is equal to 4 μm. It should be noted that W_{T} is measured, as shown, between the front face 312 (before metallization) of the semiconductor support taken at the level of the source layer 308 or of the control electrode 304 (=front face of the semiconductor support taken at the level of the etching 317 accommodating the trench cathode portion 309. The inventors have shown that the latch-up phenomena do not occur, regardless of the value for the depth of the trench W_{T}, as shown in FIG. 4 in the case of an IGBT. Similar results have been obtained for VDMOSs according to the invention which, when subjected to irradiation with heavy ions, no longer suffer burn-out, regardless of the depth of the trench. On the other hand, the value for this depth W_{T} changes the value of the threshold voltage of the transistor, except for W_{T}=4 μm in the preferred version of the invention (i.e. with L_{T}/L_{S}=16/20); this is why this value will be preferred if it is desired to provide a transistor having static operating characteristics identical to those of the corresponding standard transistor (trenchless transistor having the same dimensions except for the dimensions resulting from the trench, i.e. having the same dimensions L_{S}, Xn+, L_{G}, W_{N-}, W_{A}, L, etc., where L_{G} denotes the length of the gate contact in the transverse direction, i.e. the length of the insulated control electrode measured to the end of its oxide layer 316).

In this preferred version, the depth of overdoping (or of the body) below the trench X_{P+}, which corresponds to the maximum vertical dimension of the P⁺ overdoping region 307b at the level of the trench, is equal to 9 μm. The inventors have shown that the latch-up and burn-out phenomena do not occur when the P/P⁺ doping diffusion has a depth of 9 μm or more in the configuration corresponding to the preferred version of the invention (i.e. with the other dimensional values stated in the preceding paragraphs) as shown by the results presented in FIG. 6, established with IGBTs according to the invention for which L_{T}=16 pm, Lₛ =20 pm, W_{T} =4 pm and Xₚ₊varies, and with a standard comparable IGBT (trenchless IGBT having the same dimensions apart from the dimensions resulting from the trench). Now, this value of 9 μm for X_{P+} also ensures that the threshold voltage is maintained with respect to a standard structure.

The inventors have also shown that the proposed trench cathode portion has no influence on the dynamic behaviour of the (VDMOS and IGBT) transistors with respect to the corresponding standard structures. Only a slight reduction in the peak anode current is noted, due to the reduction in the conductive region (region between junction J2 and junction J1) following etching of the trench. In fact, the vertical distance between junctions J1 and J2 reduces with respect to the corresponding transistor of the prior art (trenchless transistor having identical dimensions), since junction J2 is offset downwards by a distance equal to W_{T}, for an equal X_{P+} overdoping depth. If is it desired to retain the same peak current, it is sufficient to “lower” junction J1 in order to retain the distance J1-J2 of the transistor of the prior art, or more generally, to compensate for the loss of conductive surface area.

In order to obtain the transistor shown in FIG. 3, it is proposed to carry out firstly, the etching 317 by a conventional dry etching process of reactive ion etching (RIE) on a virgin silicon substrate; all the technological steps for a conventional IGBT are then carried out: producing the body 307, including a step of P implantation from the front face 312 with a boron dose that can be 10¹⁶/cm² for example; producing the overdosing region 307b around the etching, including a step of P+ implantation from the front face with a boron dose that can be 10¹⁹/cm² for example; producing each source layer 308 by N+ implantation from the front face; metallization and opening of the contacts 302, 303.

It should be noted that, in order to obtain the desired depth of junction at the level of the P+ diffusion (junction J2) at the base of the trench, a fairly long curing time (greater than 5 hours) may be necessary. Furthermore, usually, a step of nitride deposition (Si₃N₄) is carried out before that of opening of the contacts. In order to open the contacts, a dry etching is necessary. However, as the nitride is deposited isotropically, including on the flanks of the trench after etching that is itself anisotropic, insulation may remain on the vertical walls of the trench, severely degrading the quality of the cathode contact. It is therefore preferable to replace this nitride deposition with an oxide that can itself be removed by isotropic wet etching. The oxide can thus be removed from the flanks of the trench.

The inventors have been able to note that, in a VDMOS according to the invention placed in extreme conditions and in particular bombarded with heavy ions, there is no initiation of the parasitic transistor and therefore no burn-out, regardless of the path of these ions within the substrate and the polarization voltage in the off-state. On the other hand, a standard VDMOS of the prior art is sensitive to all these ions starting from 15% of its breakdown voltage.

In an IGBT according to the invention, no destructive phenomenon occurs, in the off-state, for a polarization voltage that can reach up to more than 80% of the breakdown voltage. Thus for example, no destructive phenomenon was noted up to a polarization voltage of 500 V (see FIG. 7, where “SEB” signifies “Single Event Burn-out”, i.e. a single destructive event, and where the parameter “R” denotes the “range” i.e. the depth of penetration of the heavy ion into the transistor from the front face), while this same voltage is limited to 90 V in a standard IGBT of the prior art, for one and the same breakdown voltage of 600 V in both structures.

The invention can be the subject of numerous variants vis-à-vis the preferred embodiment described above, provided that these variants remain within the scope delimited by the attached claims. Thus for example, the form of the trench cathode portion can be different from that illustrated (rectangular cross section) and its dimensions different from those proposed for the preferred version.

1. Power transistor with a vertical structure having a cell exhibiting a plane of symmetry (P1) and comprising a semiconductor support 301, as well as
inside the semiconductor support (301):
two symmetrical source layers (308), having a first type of conductivity (N⁺), starting from a front face (312) of the semiconductor support, said source layers (308) being symmetrical with respect to the plane of symmetry (P1).
a body layer (307) having a second type of conductivity (P) opposite to the first type, said body layer comprising an overdoping region (307b) that extends from one source layer (308) to the other,
an NP source/body junction (J3) between each source layer (308) and the body layer (307/307b).
on the front face (312) of the semiconductor support, a first power supply electrode (302), called cathode, short-circuiting the two source layers (308) and the body layer (307/307b), as well as an insulated control electrode (304), said insulated control electrode (304) being flat,
a second power supply electrode (303) called anode, on a rear face (311) of the semiconductor support, the rear face being opposite the front face (312).
characterized in that:
the cathode has a trench portion (309) formed in an etching (317) arranged in the front face (312) of the semiconductor support between the two source layers (308), said trench cathode portion (309) comprising a base (313) extending into the body layer (307) at a distance depthwise from the NP source/body junction (J3),
the overdoping region (307b) extends below the base (313) of the trench cathode portion (309) and at least partially below each source layer (308),
the etching (317) has a ratio L_{T} to L_{S} (L_{T}/L_{S}) here called standard trench length, greater than or equal to 15/20, where L_{T} denotes half of a maximum dimension of the etching (317) in a transverse direction orthogonal to the plane of symmetry (P1) of the cell and Ls denotes the distance between the plane of symmetry (P1) and the insulated control electrode (304) in the transverse direction.

2. Power transistor according to claim 1, characterized in that the cell also comprises, in the semiconductor support (301):
an epitaxial layer (306), of the first type of conductivity, below the body layer (307),
and a PN body/epitaxial layer(J2) between the body layer (307) and the epitaxial layer (306).
and in that the base (313) of the trench cathode portion (309) extends depthwise at a distance from the PN body/epitaxial junction (J2).

3. Power transistor according to claim 1, characterized in that the trench cathode portion (309) forms an edge (315) in the body layer (307b), at a distance from the NP source/body junction (J3).

4. Power transistor according to claim 1 characterized in that the trench cathode portion (309) has lateral walls (314) that are vertical.

5. Power transistor according to claim 1, characterized in that, for each source layer, the ratio W_{T} to X_{N+} is greater than or equal to 2,
where W_{T}, called depth of trench, denotes a maximum dimension of the etching (317) in a vertical direction, and X_{N+}, called depth of the source layer, denotes a maximum dimension of the source layer (308) in the vertical direction.

6. Power transistor according to claim 5, characterized in that the ratio W_{T} to X_{N+} is equal to 4.

7. Power transistor according to claim 1, characterized in that, for each source layer (308), the difference between W_{T} and X_{N+} is at least equal to 1 μm,
where W_{T}, called depth of trench, denotes a maximum dimension of the etching (317) in a vertical direction, and X_{N+}, called depth of the source layer, denotes a maximum dimension of the source layer (308) in the vertical direction.

8. Power transistor according to claim 1, characterized in that W_{T}=4 μm, L_{T}=16 μm, X_{P+}=10 μm,
where W_{T} denotes a maximum dimension of the etching (317) in a vertical direction,
L_{T} denotes half of a maximum length of the etching (317) in the transverse direction,
and X_{P+} denotes a maximum dimension, in the vertical direction, of the overdoping region (307b) at the level of the etching (317).

9. Power component, characterized in that it comprises a multitude of power transistors according to claim 1, formed on one and the same semiconductor support (301).
